(19) United States
(12) Patent Application Publication
(10) Pub. No.: US 2022/0298671 A1
(43) Pub. Date: Sep. 22, 2022

(54) CRYSTAL GROWING ASSEMBLY WITH COMBINATION LIFT ARM AND WINCH

(71) Applicant: Linton Crystal Technologies Corp., Rochester, NY (US)

(72) Inventors: John A. Reese, Rochester, NY (US); Joel C. Stefl, Rochester, NY (US); Brian M. Repman, Rochester, NY (US)

(21) Appl. No.: 17/675,708

(22) Filed: Feb. 18, 2022

Related U.S. Application Data
(60) Provisional application No. 63/162,744, filed on Mar. 18, 2021.

(51) Int. Cl. C30B 15/30; C30B 15/20

(52) U.S. Cl. CPC C30B 15/30; C30B 15/20

(57) ABSTRACT

A lift arm can be rotatably mounted to a crystal growing apparatus to service a hot-zone of the crystal growing apparatus. A low-speed, high-power lift arm actuator can control vertical positioning of the lift arm. Movable clamp arms secured to the lift arm can engage a lip of a furnace tank to facilitate lifting and moving the furnace tank to a desired location by correlated raising, lowering, or rotating of the lift arm. A winch mounted to a distal end of the lift arm can control spooling of a cable that passes through an interior of the lift arm and out an opening between the clamp arms. The cable can include an attachment mechanism for coupling to a crucible. The winch can thus lift the crucible at vertical speeds far in excess of the lift arm actuator's vertical speed.

### CROSS-REFERENCE TO RELATED APPLICATIONS

This application claims priority to U.S. Provisional Patent Application No. 63/162,744, filed Mar. 18, 2021, which is hereby incorporated by reference herein in its entirety.

### TECHNICAL FIELD

The present disclosure relates to crystal growth equipment generally and more specifically to a combination lift arm for lifting both a furnace tank and a crucible.

### BACKGROUND

Large crystals, especially monocrystalline ingots, are extremely important to various fields of technology. With respect to modern electronics, monocrystalline silicon is an especially important source material used for various functions, such as wafers for integrated circuits and components of photovoltaic panels. A monocrystalline structure includes a continuous crystal lattice without grain boundaries, and can be made of a single element or of multiple elements (e.g., doped materials).

One manufacturing technique often used to create monocrystalline silicon is the Czochralski method, which involves dipping a seed crystal into a rotating molten bath of material, then slowly pulling the seed crystal away from the molten bath while counter-rotating the seed crystal. Solid material is pre-charged in a crucible before being brought to the crystal growing apparatus and lowered into the furnace tank, often by an overhead crane or drivable crane. There, the material is heated to a molten state. Multiple crystal growing apparatuses generally share a single drivable crane, such that movement of a first crucible to a first crystal growing apparatus must wait until after the crane has finished installing a second crucible in a second crystal growing apparatus. Once placed in the furnace tank, the cover of the crucible can be removed and a tank cover moved into place, thus permitting the seed crystal to be lowered, through an opening in the tank cover, to the molten material within the crucible.

However, care must be taken to ensure the molten material and furnace tank remain free of contaminants. Even slight contaminants can cause the crystal growing process to fail. For example, contaminants that make their way into the molten material can impact the ingot being formed, possibly resulting in a polycrystalline ingot or an ingot with inclusions or other features that affect the properties of the ingot, which may render the ingot unsuitable for its intended purpose. There is a risk that contaminants present on the drivable crane may fall into the furnace tank during crucible installation, which may result in those contaminants finding their way into the molten material once the crucible's sealing cap is removed.

Additionally, speed and convenience of crucible installation and removal can be very important to maintain factory efficiency. Use of slower actuators (e.g., overpowered actuators normally used to lift furnace tanks) and delay waiting for equipment to become free can significantly increase the time between ingot formation, resulting in added costs (e.g., from workplace costs and equipment usage) and lower yields (e.g., average ingots per week).

There is a need for improved mechanisms and techniques for efficiently moving and installing a crucible within a crystal growing apparatus's furnace tank.

### SUMMARY

Certain aspects of the present disclosure relate to a lift arm assembly for a crystal growing apparatus. The lift arm comprises a lift arm body having an arm upright and an arm tube extending distally from the arm upright; a cable having a proximal region and a distal region; a winch coupled to the lift arm body, the winch having a spool coupled to the proximal region of the cable to move the distal region between a raised position and a lowered position; a pulley positioned within the arm tube for supporting the cable and directing the cable through a cable opening of the arm tube; and an expandable shroud having a top end coupled to the arm tube around the cable opening and a bottom end coupled to the distal region of the cable, wherein a sealed environment is defined in part by the expandable shroud, the distal region of the cable, and the arm tube, wherein the expandable shroud is in a compressed configuration when the distal region of the cable is in a raised position, and wherein the expandable shroud is in an expanded configuration when the distal region of the cable is in a lowered position.

Certain aspects of the preset disclosure relate to a crystal growing apparatus comprising a furnace tank having an opening; a support tower; an upper section removably couplable to the opening to establish a crystal growing chamber, the upper section comprising a receiving tube coupled to a seed lift assembly, wherein the upper section is rotatably coupled to the support tower to rotate between an installed orientation and an uninstalled orientation, wherein the upper section is positioned over the furnace tank when in the installed orientation, and wherein the upper section is rotated away from the furnace tank when in the uninstalled orientation; a lift arm assembly rotatably coupled to the support tower to rotate between a hot-zone orientation and a displaced orientation, the lift arm assembly including: a lift arm body comprising an arm upright and an arm tube extending distally from the arm upright; a cable having a proximal region and a distal region, the distal region including an attachment mechanism that is removably couplable to a crucible cover of a crucible positionable within the furnace tank; a winch coupled to the lift arm body, the winch having a spool coupled to the proximal region of the cable to move the distal region between a raised position and a lowered position at a first speed; a pulley positioned within the arm tube for supporting the cable and directing the cable through a cable opening of the arm tube; and an expandable shroud having a top end coupled to the arm tube around the cable opening and a bottom end coupled to the distal region of the cable, wherein a sealed environment is defined in part by the expandable shroud, the distal region of the cable, and the arm tube, wherein the expandable shroud is in a compressed configuration when the distal region of the cable is in a raised position, and wherein the expandable shroud is in an expanded configuration when the distal region of the cable is in a lowered position; and a lift arm actuator actuatable to move the lift arm assembly between an upper position and a lower position up to a second speed, wherein the first speed is faster than the second speed.

Certain aspects of the present disclosure relate to a method for using a crystal growing apparatus, the method comprising providing a furnace tank having a lip; positioning a lift arm assembly over the furnace tank, wherein the lift arm assembly is rotatably coupled to a support tower, the lift arm assembly including: a lift arm body comprising an arm upright and an arm tube extending distally from the arm upright; a cable having a proximal region and a distal region, the distal region including an attachment mechanism that is removably couplable to the crucible cover; a winch coupled to a distal end of the lift arm body, the winch having a spool coupled to the proximal region of the cable to move the attachment mechanism between a raised position and a lowered position at a first speed; a pulley positioned within the arm tube for supporting the cable and directing the cable through a cable opening of the arm tube; an expandable shroud having a top end coupled to the arm tube around the cable opening and a bottom end coupled to the distal region of the cable, wherein a sealed environment is defined in part by the expandable shroud, the distal region of the cable, and the arm tube, wherein the expandable shroud is in a compressed configuration when the attachment mechanism is in a raised position, and wherein the expandable shroud is in an expanded configuration when the attachment mechanism is in a lowered position; and a set of clamp arms rotatably coupled to and extending below the arm tube, wherein each clamp arm of the set of clamp arms is movable between a clamped position and an unclamped position; installing the furnace tank, wherein installing the furnace tank includes: moving each clamp arm of the set of clamp arms to the unclamped position; actuating a lift arm actuator to lower the lift arm assembly up to a first speed until each clamp arm of the set of clamp arms passes below the lip of the furnace tank; moving each clamp arm of the set of clamp arms to the clamped position; actuating the lift arm actuator to raise the lift arm assembly and move each clamp arm of the set of clamp arms to engage the lip of the furnace tank; rotating the lift arm assembly to a hot-zone orientation; actuating the lift arm actuator to lower the lift arm assembly until the furnace tank rests within a furnace tank receiving space; moving each clamp arm of the set of clamp arms to the unclamped position; and actuating the lift arm actuator to raise the lift arm assembly; providing a crucible filled with a meltable material, the crucible having a crucible cover removably coupled to a crucible base; rotating the lift arm assembly to a position over the crucible; installing the crucible, wherein installing the crucible includes: actuating the winch to lower the attachment mechanism at a second speed, wherein the second speed is greater than the first speed; coupling the attachment mechanism to the crucible cover; actuating the winch to raise the attachment mechanism and crucible; rotating the lift arm assembly to the hot-zone orientation; actuating the winch to lower the attachment mechanism and crucible until the crucible rests within the furnace tank; disconnecting the attachment mechanism from the crucible base; and actuating the winch to raise the attachment mechanism; rotating the lift arm assembly away from the hot-zone orientation; rotating an upper section to an installed orientation over the furnace tank, the upper section being rotatably coupled to the support tower, the upper section having a seed lift assembly coupled to a receiving tube, the seed lift assembly supporting a seed crystal on a cable; and growing a crystal ingot by lowering the seed crystal to the meltable material in the crucible and raising the seed crystal while counter-rotating the seed crystal and the crucible base.

Additional implementations and/or aspects of the present disclosure will be apparent to those of ordinary skill in the art in view of the detailed description of various implementations, which is made with reference to the drawings, a brief description of which is provided below.

### BRIEF DESCRIPTION OF THE DRAWINGS

The specification makes reference to the following appended figures, in which use of like reference numerals in different figures is intended to illustrate like or analogous components.

FIG. 1 is an isometric diagram depicting a crystal growing apparatus with a lift arm assembly, according to certain aspects of the present disclosure.

FIG. 2 is a graphical projection depicting a lift arm assembly, according to certain aspects of the present disclosure.

FIG. 3 is a front view a lift arm assembly, according to certain aspects of the present disclosure.

FIG. 4 is a front view of a winch assembly supporting an attachment mechanism in a raised position, according to certain aspects of the present disclosure.

FIG. 5 is a front view of a winch assembly supporting an attachment mechanism in a lowered position, according to certain aspects of the present disclosure.

FIG. 6 is a side view of a winch on a lift arm assembly, according to certain aspects of the present disclosure.

FIG. 7 is a front view of a portion of a lift arm assembly supporting a furnace tank, according to certain aspects of the present disclosure.

FIG. 8 is an isometric view of a portion of a crystal growing apparatus depicting an arm rotation assembly for rotating a lift arm assembly, according to certain aspects of the present disclosure.

FIG. 9 is a flowchart depicting a process of using a crystal growing apparatus with a lift arm assembly, according to certain aspects of the present disclosure.

### DETAILED DESCRIPTION

Certain aspects and features of the present disclosure relate to a lift arm for a crystal growing apparatus. The lift arm can be rotatably mounted adjacent a hot-zone of a crystal growing apparatus, allowing the lift arm to be rotated over or away from the hot-zone. A low-speed, high-power lift arm actuator can control vertical positioning of the lift arm. Movable clamp arms secured to the lift arm allow the lift arm to lift and move a furnace tank by engaging a lip of the furnace tank with the clamp arms and then raising, lowering, or rotating the lift arm to move the furnace tank to a desired location. A winch mounted to a distal end of the lift arm can control spooling of a cable that passes through an interior of the lift arm and out an opening between the clamp arms. The cable can include an attachment mechanism for coupling to a crucible, allowing the crucible to be lifted by the winch, thus lifting the crucible at a much faster speed than would be capable using the lift arm actuator. Thus, the combination lift arm is capable of both lifting a furnace tank using the lift arm actuator and lifting a crucible using a faster-speed winch.

Certain crystal growth techniques, such as the creation of monocrystalline silicon ingots, makes use of a seed crystal suspended above a melt of material (e.g., metalloids, such as silicon) within a sealed enclosure. The melt is retained within a crucible, which is placed within a furnace tank to control the temperature of the melt. An upper section that includes a receiving chamber and a seed lift assembly is couplable to the furnace tank to establish a controlled environment. The seed crystal is supported by the seed lift assembly, which can raise, lower, or rotate the seed crystal as needed. During a crystal growing process, the seed crystal is lowered to contact the melt, then raised and rotated in a controlled fashion to permit formation of a nascent ingot of crystallized material (e.g., the growing crystal). As the seed crystal continues to be lifted away from the surface of the melt, the nascent monocrystalline ingot continues to grow until a desired length has been reached. The seed crystal and nascent ingot can be drawn vertically up into the receiving chamber above the melt.

The crystal growing process can take different amounts of times depending on the end size of the ingot. In an example, growing of a cylindrical ingot of monocrystalline silicon to approximately 5-7 meters in length may take multiple days. Any contaminants in the furnace tank or crucible can result in significant defects in the resultant ingot, which may lead to a failed ingot. A failed ingot may need to be re-melted and re-grown, which can be very expensive (e.g., in money and time), especially if the failure occurs near the end of a multi-day crystal growing process. Certain aspects of the present disclosure relate to improvements that permit a seed growing system to operate with reduced opportunity for contaminants to enter the furnace tank or crucible.

The crystal growing apparatus can generally include a support tower that supports an upper section and a lift arm adjacent a hot-zone. The hot-zone includes a heater (e.g., one or more heating elements, such as an inductive heating element or a radiant heating element) for controlling the temperature of the furnace tank during the crystal growing process. The upper section is rotatably coupled to the support tower by an upper section arm. In some cases, the upper section arm is mounted to a first vertical shaft, allowing the upper section to rotate about the first vertical shaft. The vertical arm can rotate between an installed orientation, in which the receiving chamber is located over the hot-zone, and an uninstalled orientation, in which the receiving chamber is rotated away from the hot-zone.

A lift arm can be rotatably coupled to the support tower, such as by a second vertical shaft. The lift arm can include a vertical arm upright coupled to an arm tube. As used herein, the term arm tube is intended to describe a weight-bearing structure extending from the arm upright and having a cavity in which a cable can pass. The term arm tube is inclusive of single-body extrusions or multi-body pieces coupled together (e.g., via welding or attachment devices). For example, the arm tube can be a weldment having a generally rectangular cross section. The cavity of the arm tube can extend the full length of the arm tube or less than the full length of the arm tube. When the arm upright is rotatably coupled to the support tower, the arm tube can extend distally from and cantilever from the arm upright.

The lift arm can rotate between a hot-zone orientation, in which the lift arm is positioned over the hot-zone, and a displaced orientation, in which the lift arm is rotated away from the hot-zone. Thus, the lift arm can rotate into the hot-zone orientation after the upper section has rotated to the uninstalled orientation. As used herein, the terms installed orientation, uninstalled orientation, hot-zone orientation, and displaced orientation can refer to angular positions around an axis of rotation, and can be independent on the height of the object. For example, a lift arm in a hot-zone orientation can remain in the hot-zone orientation despite being raised or lowered.

While described as a “tower,” the support tower can take any suitable shape or form, such as a floor-mounted structure, a wall-mounted structure, a ceiling-mounted structure, a support-frame-mounted structure, or the like. In some cases, the support tower can include two or more separate structures that are fixed with relation to one another, such as by being fixedly coupled to the floor. Thus, as used herein, an upper section and a lift arm coupled to a support tower can include i) both the upper section and lift arm being coupled to the same support structure; or ii) the upper section being coupled to a first support structure and the lift arm being coupled to a second support structure that is fixed with respect to the first support structure. In a first example, a support tower can take the form of a vertical post mounted to the floor. In a second example, the support tower can take the form of an elongated wall positioned adjacent multiple hot-zones. In a third example, the support tower can take the form of a first vertical post fixedly coupled to the floor adjacent a second vertical post fixedly coupled to the floor.

Between crystal growing processes, the upper section can be decoupled from the furnace tank and moved to the side (e.g., the uninstalled orientation) to allow access to the furnace tank and crucible therein. The furnace tank sits within a hot-zone, which can refer to the region of the crystal growing apparatus in which the furnace tank is placed during the crystal growing process. The crucible is designed to be removable from the furnace tank, allowing the crucible to be pre-charged with solid silicon or meltable material prior to being placed in the furnace tank for a crystal growing process. The furnace tank is removable from the hot-zone to facilitate maintenance to the hot-zone and/or furnace.

Removal of the furnace tank generally includes rotating the lift arm into the hot-zone orientation, lowering the lift arm to the furnace tank, securing the furnace tank to the lift arm, raising the lift arm, and rotating the lift arm towards the displaced orientation. A reversed process can be used to install the furnace tank. Securing the furnace tank to the lift arm can be performed in any suitable manner. In some cases, the lift arm includes a set of clamp arms (e.g., two, three, or more clamp arms) designed to engage a lip of the furnace tank. The clamp arms are generally movable between an unclamped position and a clamped position. In the unclamped position, the lift arm can be lowered to the furnace tank such that the ends of the clamp arms are below the lip. Then, the clamp arms can be moved to the clamped position such that raising of the lift arm engages the clamp arms with the lip. Clamp arms may or may not make contact with the wall of the furnace tanks. In some cases, clamp arms apply vertical force to the furnace tank via its lip, without applying horizontal force towards the center of the furnace tank. The lip of the furnace tank can be any surface that extends beyond the circumference of the top of the wall of the furnace tank. In some cases, the lip can be continuous with the wall of the furnace tank. In other cases, the lip can be coupled to (e.g., welded to) the wall of the furnace tank. In some cases, the lip can pass around the entire circumference of the furnace tank, although that need not always be the case. In some cases, the lip can include multiple, discrete lip segments that are located at different angular positions around the center of the furnace tank. For example, a lip can include two brackets coupled to the furnace tank at opposite sides of the furnace tank. In some cases, the lip can have a bottom surface that is smaller than an upper surface (e.g., a V-shaped lip or W-shaped lip), allowing the lip to seat within a corresponding feature of a clamp arm.

In some cases, movement of the clamp arms between clamped and unclamped positions can be performed manually, such as manually moving the clamp arm into position by hand and securing the clamp arm in that position using a clevis pin or other technique. In some cases, however, movement of the clamp arms can be effected through the use of controllable clamp actuators. Any suitable clamp actuators can be used, such as hydraulic or pneumatic pistons, solenoids, other linear actuators (e.g., a leadscrew-and-motor actuator), and non-linear actuators (e.g., servo motors). Such clamp actuators can be controlled by manual input or can be automated. Controlled clamping can permit the furnace tank to be coupled to the lift arm in a hands-off fashion, thus keeping workers away from dangerous areas as the furnace tank is clamped and optionally lifted and moved.

Thus, movement of the furnace tank can be effected by raising and lowering the lift arm. A lift arm actuator can control vertical movement of the lift arm. In some cases, the lift arm actuator is a hydraulic cylinder. In some cases, the vertical shaft to which the lift arm is rotatably coupled can be the shaft of the hydraulic cylinder. Thus, actuation of the hydraulic cylinder can effect raising or lowering of the lift arm, while the lift arm is separately able to rotate about the shaft axis. In some cases, other actuators can be used to raise or lower the lift arm, such as a ball-and-screw actuator. Because of the weight of the lift arm, especially in combination with the weight of the furnace tank (e.g., approximately 2,000 kg), the lift arm actuator is generally a high-power actuator that operates at a relatively low speed (e.g., on the order of tens of mm per second, such as 10-15 mm/sec).

Installation of the crucible generally involves securing a crucible lid to the crucible base, then lifting the crucible by one or more lift points (e.g., an eyelet secured at the center of the crucible lid) on the crucible lid. Common practices involve bringing a fork-lift or other mobile equipment to the crystal growing apparatus, then using that equipment to remove the crucible. However, such practices require halting operations at a given crystal growing apparatus until that piece of mobile equipment is free. When many crystal growing apparatuses are collocated, this wait time can be significant. Additionally, use of this type of mobile equipment increases the risk of contaminants falling into the furnace tank or crucible, especially during crucible installation. Mobile equipment, especially if used for other purposes in addition to crucible movement, can quickly collect contaminants and must undergo more frequent and specialized maintenance (e.g., sanding and repainting with special paint) to ensure contaminants (e.g., rust or flaking paint) do not fall from the equipment.

In some cases, a hook attached to the lift arm can be used to move the crucible without waiting for mobile equipment. However, existing lift arms only raise and lower at the relatively slow speeds mentioned above. Thus, the time required to remove the crucible and place it elsewhere can be very long. This time would be even longer in cases where the lift arm is raised to its uppermost position before rotation.

Certain aspects of the present disclosure include a lift arm that includes a winch capable of controlling the vertical movement of an attachment mechanism supported by a cable. The winch can be located at any suitable location on the lift arm. In some cases, however, the winch can be located at a distal end (e.g., end furthest from the axis of rotation of the lift arm) of the lift arm. Winch placement at the distal end can improve access to the winch for service purposes, can keep the winch away from potential pinch points (e.g., adjacent the axis of rotation of the lift arm), and can reduce the risk of contaminants from the winch falling into the furnace tank or crucible (e.g., since the winch moves in an arc outside of the range of the furnace tank).

In some alternate cases, the winch can be located in a location other than the distal end of the lift arm. In some cases, the winch can be located i) at the top of or above the arm tube, centered with the cable opening; ii) between the cable opening and the arm upright; or iii) on an extension arm supporting a clamp arm at a distance from the arm tube. In some cases, the winch can be mounted such that it is partially enclosed within the arm tube. In such an example, the spool may be rotatably mounted within the arm tube and driven by a winch motor and gearbox that are either separately mounted within the arm tube or mounted external to the arm tube.

The winch can include a spool coupled that is coupled to a cable at a proximal region of the cable. The cable can pass through an interior of the lift arm (e.g., through an arm tube), over a pulley, and out a cable opening (e.g., an opening on a lower surface of the arm tube). A pulley cover or pressure roller can be used to ensure any slack in the cable does not cause the cable to be unseated from the pulley. The cable opening can be placed in any suitable location along the lift arm, although in some cases it is placed between the clamp arms. In some cases, the cable opening is centered between the clamp arms (e.g., equidistant from each clamp arm). The distal region of the cable can include an attachment mechanism. Any suitable attachment mechanism can be included, such as an eyelet, a hook, a clevis fastener, and the like.

The winch can include a spool for spooling up the cable. The spool can be coupled to a limit switch assembly that provides a signal whenever the cable is spooled in and/or out to threshold points. For example, a first limit switch can be actuated when the cable is spooled in sufficiently such that the attachment mechanism reaches a raised position, and a second limit switch can be actuated when the cable spooled out sufficiently such that the attachment mechanism reaches a lowered position (e.g., before the expandable shroud reaches a limit of expansion or before the attachment mechanism reaches the floor level). In some cases, the limit switch assembly includes a leadscrew mechanically coupled to the spool such that rotation of the spool induces rotation of the leadscrew. A contacting surface can be coupled to the leadscrew via a nut, such that rotation of the leadscrew moves the contacting surface axially along the axis of the leadscrew. The limit switches can be placed such that the contacting surface engages the appropriate limit switch at the appropriate time.

To further protect against contaminants falling into a crucible or furnace tank, an expandable shroud can be positioned at the cable opening and be coupled to the distal region of the cable. A top end of the expandable shroud can be coupled to the arm tube and optionally sealed, such as with a gasket. A bottom end of the expandable shroud can be coupled to the attachment mechanism, to the cable itself, or can be sandwiched between the attachment mechanism and a cable collar such that translation of the attachment mechanism up and down also induces the same translation in the bottom end of the expandable shroud. In some cases, the bottom end of the expandable shroud includes a gasket or other suitable seal to create a dust-proof barrier between the cable and the expandable shroud.

The top end and bottom end of the expandable shroud can be connected by an expandable section. The expandable section can be made of an expandable material and/or can include expandable features, such as pleats or folds (e.g., accordion folds) or nesting covers (e.g., telescoping, nested columns). The expandable shroud can provide a dust/debris barrier between the inside of the arm tube and the environment over the furnace tank or crucible. Thus, there is no need to treat or continually maintain the inside of the arm tube, the pulley within, the winch, or non-exposed cable, which may otherwise be needed to avoid risk of contamination.

In some cases, instead of or in addition to an expandable shroud, certain aspects of the present disclosure can make use of a cable wipe designed to wipe off and remove dust or debris from the cable as it exits the arm tube. In some cases, instead of passing through the arm tube, the cable can pass through a cable guide mounted to the arm tube (e.g., mounted below the arm tube).

While the winch is described herein primarily with respect to lifting a crucible, it can be used to lift other equipment as well, such as other hot-zone equipment. For example, in some cases, the winch can be used to lift a heater or shielding (e.g., a gas shield) used in the hot-zone. In some cases, the winch can be used to lift a crucible support shaft.

The winch scan be controlled by any suitable controller. In some cases, the winch can be controlled by a remote controller. In some cases, the controller can lockout certain functions of the winch (e.g., raising, lowering, or both) depending on the state of other elements of the crystal growing apparatus. For example, the winch may be locked out from lowering whenever the clamp arms are clamping an object (e.g., a furnace tank).

Certain aspects and features of the present disclosure relate to an arm rotation assembly for controllable rotation of the lift arm. The arm rotation assembly can be located at the vertical shaft upon which the lift arm is mounted, above the lift arm. The arm rotation assembly can be rotatably coupled to the vertical shaft and mechanically coupled to an arm rotation driver. The arm rotation driver can be any suitable controllable driver for rotating the arm rotation assembly. In some cases, the arm rotation driver is a motor that is coupled to the arm rotation assembly via a gearbox and belt to achieve a sufficiently high torque to rotate the lift arm.

The arm rotation assembly includes a keyseat for receiving a corresponding key of the lift arm. As used herein, the terms keyseat and key are inclusive of any suitably corresponding mechanical features that permit rotational movement of the key when the key is inserted into the keyseat and the keyseat is turned. In some cases, the keyseat of the arm rotation assembly is a U-shaped piece with legs that extend out from the vertical shaft. In such cases, the key of the lift arm can be a region of the arm upright that fits between the legs of the U-shaped keyseat of the arm rotation assembly. Thus, when the lift arm is raised to a sufficient height, rotation of the arm rotation assembly will induce corresponding rotation of the lift arm. However, when the lift arm is lowered below a threshold height, its key will no longer be within the keyseat of the arm rotation assembly, and thus rotation of the arm rotation assembly would not induce rotation of the lift arm.

In some cases, the arm rotation assembly can be held in place with sufficient friction (e.g., from a gearbox coupling the arm rotation assembly and arm rotation driver) such that when the lift arm is raised above the threshold height, the arm rotation assembly will provide resistance to rotation of the lift arm until the arm rotation assembly is itself driven to rotate by the arm rotation driver.

Use of the arm rotation assembly can permit automated movement of the lift arm, such as for installation or removal of the furnace tank or crucible. Use of such an arm rotation assembly can be especially useful in cases where the lift arm includes a winch. In such cases, the lift arm may be supporting a heavy object (e.g., pre-charged crucible filled with silicon or another meltable material) by a single cable, and thus rotational acceleration of the lift arm may lead to undesirable swaying of the heavy object. Being a controllable device, the arm rotation driver can drive the arm rotation assembly to slowly rotate the lift arm at a constant speed, thus avoiding undesirable (e.g., dangerous) swaying. Additionally, since the rotation can now be automated, fewer or no workers may be required to supervise or assist with the rotation, thus permitting those workers to perform other tasks during that time.

Certain aspects of the present disclosure provide a clean, convenient, and safe technique for maintaining the inner workings of the hot-zone. By having both furnace tank clamp arms and a winch with an enclosed cable collocated on the same lift arm, common maintenance and repeated tasks requiring either a high-power lift or a faster lift can be accomplished with the same equipment. Additionally, by including the furnace tank lift and pre-charged crucible lift on the same lift arm that is part of the crystal growing apparatus, there is no longer any need to wait for equipment to free up before it can be used. Further, the processes of grabbing and moving the furnace tank and moving the crucible can be automated or controlled remotely.

These illustrative examples are given to introduce the reader to the general subject matter discussed here and are not intended to limit the scope of the disclosed concepts. The following sections describe various additional features and examples with reference to the drawings in which like numerals indicate like elements, and directional descriptions are used for illustrative purposes, but should not be used to limit the present disclosure. The elements included in the illustrations herein may not be drawn to scale.

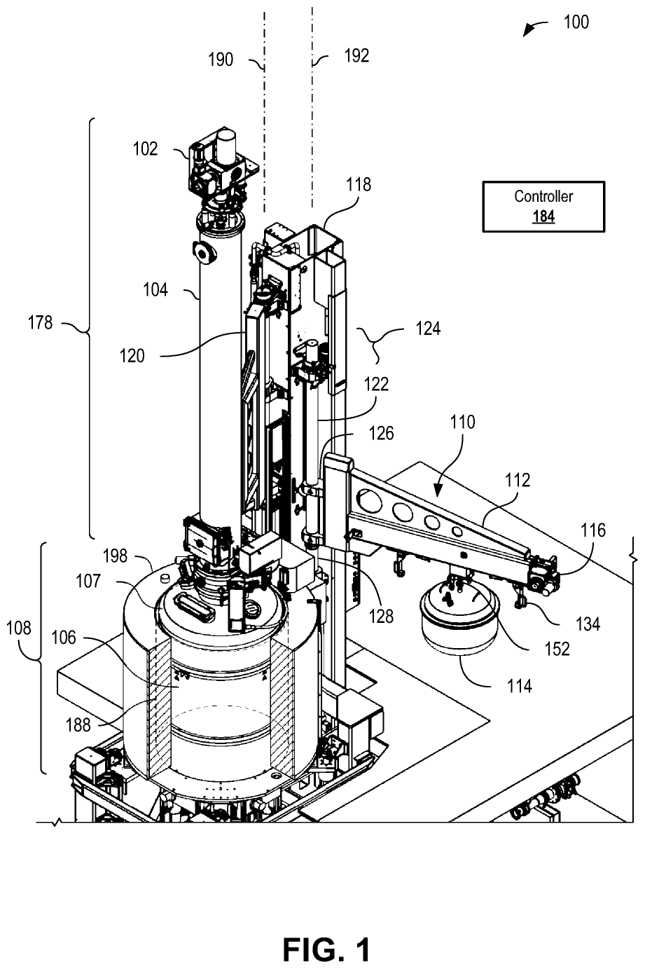

FIG. 1 is an isometric diagram depicting a crystal growing apparatus 100 with a lift arm assembly 110, according to certain aspects of the present disclosure. The crystal growing apparatus 100 can be used to create monocrystalline ingots from a suitable molten material, such as silicon. The crystal growing apparatus 100 can include a hot-zone 108 having a furnace receiving space 188 in which a furnace 106 can be placed. For illustrative purposes, the furnace receiving space 188 is depicted in dashed lines. In some cases, the furnace receiving space 188 is located within a magnet assembly 198, which can be used to generate magnetic fields that facilitate control of fluid flow within the molten melt (e.g., to offset convective forces within the molten melt). For illustrative purposes, the magnet assembly 198 is depicted in partial sectional view to permit the furnace 106 to be depicted. The furnace 106 itself or surrounding equipment can include thermal insulation to better insulate the environment within the furnace 106 with respect to the surrounding environment. The furnace 106 can include a furnace cover 107. The hot-zone 108 can include additional equipment, such a crucible shaft and crucible pedestal within the furnace 106 for supporting and rotating a crucible 114, one or more heating elements for maintaining a desired temperature within the furnace 106, and shielding (e.g., gas shielding for directing gas flow within the controlled environment of the crystal growing apparatus 100 (e.g., to direct gas flow from the upper section 178, over the crucible, and out a gas outlet of the furnace 106). As depicted in FIG. 1, the crucible 114 is positioned outside of the furnace tank 106, although crucible 114 would be within the furnace tank 106 during a crystal growing process.

The crystal growing apparatus 100 can include an upper section 178 that includes a seed lift assembly 102 supported by a receiving tube 104. The seed lift assembly 102 can support a seed crystal from a cable within the receiving tube 104, and is rotatably coupled to the receiving tube 104 to permit the seed lift assembly 102 to rotate the seed crystal with respect to the receiving tube 104. The receiving tube 104 can couple to the top of the furnace tank 106 (e.g., via the furnace cover 107, an isolation valve, and/or additional coupling mechanisms). When the receiving tube 104 is coupled to the furnace tank 106, an internal environment can be defined, at least in part, by the space within the furnace tank 106 and receiving tube 104. This internal environment can be controlled to maintain desired temperatures and/or cleanliness. To perform a crystal growing process, the seed crystal can be lowered down to the melt within the crucible 114 (when the crucible 114 is within the furnace 106) and slowly raised and rotated as the crucible 114 is rotated in an opposite direction. The nascent ingot can then be formed and pulled up within the receiving tube.

The upper section 178 can be coupled to a support tower 118 via an upper section arm 120 to rotate about an axis of rotation 190. The upper section 178 can rotate between an installed orientation and an uninstalled orientation. In the installed orientation, the upper section 178 can be located over the hot-zone 108 (e.g., centered above the hot-zone 108 or furnace tank 106 such that the upper section 178 is either coupled to the furnace tank 106 or could be lowered to couple to the furnace tank 106). The upper section 178 can be rotated away from the installed orientation and towards an uninstalled orientation in which the upper section 178 is not positioned over the hot-zone 108. As depicted in FIG. 1, the upper section 178 is in an installed orientation, but could be moved to an uninstalled orientation by decoupling the upper section 178 from the furnace 106, raising the upper section 178, and rotating the upper section 178 about axis of rotation 190 in a clockwise direction when looking at the upper section 178 from above. An actuator (e.g., hydraulic cylinder or other suitable actuator) can control vertical movement of the upper section 178. For example, the upper section arm 120 may be rotatably mounted to the shaft of a hydraulic cylinder.

When the upper section 178 is in an uninstalled orientation, access to the hot-zone 108 from above is permitted, such as to maintain, install, or remove a crucible 114, a furnace tank 106, or other hot-zone components.

The crystal growing apparatus 100 can include a lift arm assembly 110 rotatably coupled to the support tower 118 about axis of rotation 192. The lift arm assembly 110 can include a lift body 112 (e.g., an arm tube extending distally from an arm upright). The lift body 112 can be rotatably coupled to a vertical shaft 122 of the support tower 118 via one or more lift arm bearings 126. A lift arm actuator 128 (e.g., hydraulic cylinder or other suitable actuator) can control vertical movement of the lift arm assembly 110. For example, the vertical shaft 122 may be the shaft of a hydraulic cylinder. An arm rotation assembly 124 can be used to effect rotation of the lift arm assembly 110 when the lift arm assembly 110 is raised past a threshold height. The lift arm bearings 126 can permit the lift arm assembly 110 to freely rotate about the axis of rotation 192 unless otherwise held in place, such as by the arm rotation assembly 124 in some cases.

The lift arm assembly 110 can include an attachment mechanism 152 suitable to couple to a crucible 114. The attachment mechanism 152 can be a hook, eyelet, clevis, or other suitable fastener or feature. Vertical movement of the attachment mechanism 152 can be effected by a winch assembly 116. The winch assembly 116 can be located in any suitable location, such as at a distal end of the lift arm body 112, as depicted in FIG. 1. The lift arm assembly 110 can further include a set of clamp arms 134 (e.g., two clamp arms 134, as depicted in FIG. 1, or greater than two). The clamp arms 134 can be positioned to secure a furnace tank 106 to the lift arm body 112, allowing the lift arm assembly 110 to raise, lower, and move the furnace tank 106.

The lift arm assembly 110 is rotatable between a hot-zone orientation and a displaced orientation. In the hot-zone orientation, the lift arm assembly 110 is positioned over the hot-zone 108 (e.g., centered above the hot-zone 108 or furnace tank 106 such that the clamp arms 134 are aligned to clamp a furnace tank 106). In the displaced orientation, the lift arm assembly 110 is not positioned over the hot-zone 108. The lift arm assembly 110 is depicted in FIG. 1 as in a displaced orientation. The lift arm assembly 110 can move from this displaced orientation to the hot-zone orientation (after the upper section has moved to an uninstalled orientation) by rotation of the lift arm assembly 110 about axis of rotation 192 in a clockwise direction when looking at the lift arm assembly 110 from above.

In some cases, the crystal growing apparatus 100 can include a controller 184, or control system. Controller 184 can be located in any suitable location, such as in, coupled to, or spaced apart from any other component of the crystal growing apparatus 100. In some cases, controller 184 is located in a separate housing. Controller 184 can provide electronic control to the various controllable components of the crystal growing apparatus 100. In some cases, controller 184 is able to control actuation of the winch assembly 116, actuation of clamp arms 134, actuation of the lift arm actuator 128, actuation of the arm rotation assembly 124, an actuator controlling height of the upper section 178, an actuator controlling rotation of the upper section 178 about axis of rotation 190, and/or any other controllable components.

The controller 184 can be coupled to one or more sensors (e.g., position sensors, limit switches, force sensors, or others) to receive sensor data associated with the components of the crystal growing apparatus 100. In some cases, the sensor data can be used to determine when a component of the crystal growing apparatus 100 has reached a certain location, orientation, or state. For example, a limit switch or a rotary encoder can be used to determine when the winch assembly 116 has moved the attachment mechanism 152 to a raised position or a lowered position. Likewise, a limit switch or a rotary encoder can be used to determine when the lift arm assembly 110 has been rotated into a hot-zone orientation. This sensor data can be leveraged to automate various actions.

In an example, once a crucible 114 has been coupled to the attachment mechanism 152, a controller 184 can perform operations that cause the winch assembly 116 to raise the crucible 114 to a secure height (e.g., adjacent the lift arm body 112); cause the lift arm assembly 110 to raise, as needed, to reach the arm rotation assembly 124; cause the arm rotation assembly 124 to rotate the lift arm assembly 110 into a hot-zone orientation; then cause the winch assembly 116 to lower the crucible 114 to a desired height over or within the furnace tank 106. Automated movement of other components can be achieved in similar fashion (e.g., automated lifting and moving of the furnace tank 106 from the hot-zone receiving space.

The controller 184 can include one or more processors and/or other elements usable to generate the control signals, as well as one or more user interface devices (e.g., displays, light emitting diodes (LEDs), buttons, keyboards, touchscreens, and the like). Any processor can be a general or special purpose processor or microprocessor. In some cases, the controller 184 can include memory for storing machine-readable instructions that are executable by one or more processors to perform the functions disclosed herein, such as controlling movement of the lift arm assembly 110. The memory can be any suitable computer readable storage device or media, such as, for example, a random or serial access memory device, a hard drive, a solid state drive, a flash memory device, etc. Memory can be non-transitory memory. Memory can include one or more memory devices. In some cases, the controller can be implemented as or can include an application specific integrated circuit (ASIC). The controller 184 can be segmented into separate sub-controllers, which can be housed in the same or separate housings.

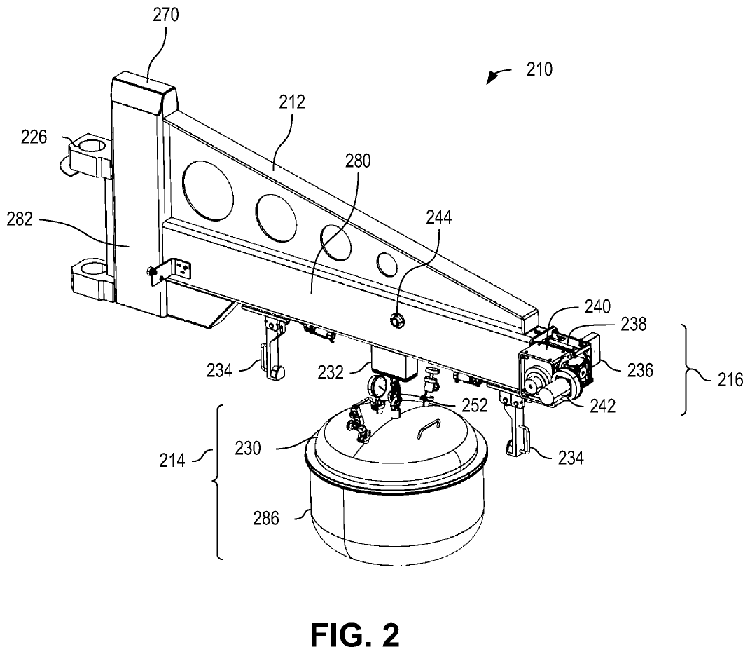

FIG. 2 is a graphical projection depicting a lift arm assembly 210, according to certain aspects of the present disclosure. Lift arm assembly 210 can be any suitable lift arm assembly, such as lift arm assembly 110 of FIG. 1.

Lift arm assembly 210 can include a lift arm body 212 that includes an arm upright 282 coupled to an arm tube 280. One or more lift arm bearings 226 can be coupled to the arm upright 282 to facilitate attachment of the arm upright 282 to the vertical shaft. In some cases, a surface of an arm bearing 226 (e.g., an extended surface of an arm bearing 226) can be used to trip a limit switch based on the height of the lift arm assembly 210.

A winch assembly 216 can be coupled to the distal end of the arm tube 280. The winch assembly 216 can include a winch motor 242, a winch gearbox 240, a spool 238, and a limit switch assembly 236. Actuation of the winch motor 242 can cause the spool 238 to spool up or spool out the cable attached thereto. The cable can pass from the winch assembly 216 directly into the arm tube 280, passing over a pulley rotating about a pulley axis 244, down out of the arm tube 280 via a cable opening, into an expandable shroud 232, until providing an attachment mechanism 252 (e.g., a hook coupled to the end of the cable).

The attachment mechanism 252 can be used to couple removably components to the lift arm assembly 210 for lifting. For example, attachment mechanism 252 can couple to a crucible lid 230 of a crucible 214. The crucible lid 230 can be secured to the crucible 286 (e.g., via a vacuum seal). Thus, the crucible 214 can be lifted from one or more lift points on the crucible lid 230, which are attachable to the attachment mechanism 252.

In some cases, lift arm assembly 210 can further include a set of clamp arms 234 usable to secure a furnace tank to the lift arm assembly 210. The clamp arms 234 can be located on opposite sides of the cable outlet, and thus on opposite sides of the expandable shroud 232. In some cases, the set of clamp arms 234 can include three or more clamp arms 234. In some cases, one or more of the set of clamp arms 234 can be located on an extension piece that extends away from the arm tube 280. For example, when three clamp arms 234 are used, the three clamp arms 234 can be placed in a 120° spread pattern, such as with a first clamp arm 234 positioned in the plane of the lift arm body 212 and the second and third clamp arms 234 positioned on extension pieces.

In some cases, lift arm assembly 210 can include a key or a key region 270. The key region 270 can be a region of the lift arm assembly 210 designed to fit with a corresponding keyseat of an arm rotation assembly. The key region 270 can be located at the top of the arm upright 282, and in some cases can include some or all of the arm upright 282 itself.

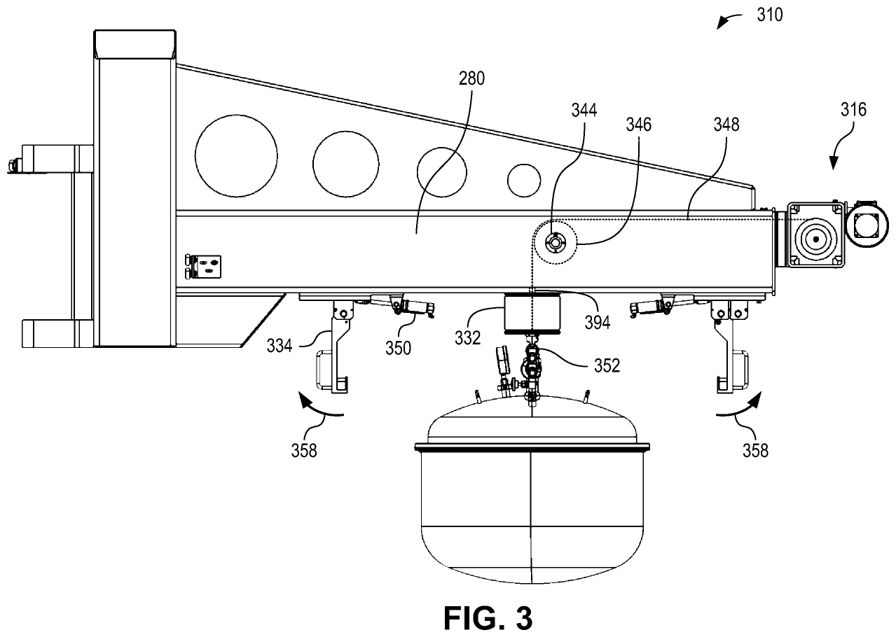

FIG. 3 is a front view a lift arm assembly 310, according to certain aspects of the present disclosure. Lift arm assembly 310 can be any suitable lift arm assembly, such as lift arm assembly 110 of FIG. 1. For illustrative purposes, cable 348, pulley 344, and cable opening 394 are depicted in dotted line.

The cable 348 can extend from the winch assembly 316 towards a pulley 346. For example, when the winch assembly 316 is located at a distal end of the arm tube 280, the cable 348 can extend proximally within the arm tube 280. The cable 348 can pass over the pulley 346, which rotates along pulley axis 344. The cable 348 can pass down and out of the arm tube 280, such as out of a cable opening 394. The cable 348 can terminate in an attachment mechanism 352, although that need not always be the case. An expandable shroud 332 can be positioned between the arm tube 308 and the lowest point of the attachment mechanism 352.

As depicted, attachment mechanism 352 is in a raised position. To lower the attachment mechanism 352 towards a lower position, the winch assembly 316 can spool out the cable 348. As the attachment mechanism 352 lowers, the expandable shroud 332 can expand in length to maintain the sealed environment within.

The set of clamp arms 334 can be positioned below the arm tube 280. Each clamp arm 334 can rotatably couple to the arm tube 280, such as via a bracket. Each clamp arm 334 can rotate between a clamped position and an unclamped position. As depicted, the clamp arms 334 are positioned in a clamped position. Rotation of clamp arms 334 in directions 358 (e.g., outward directions) move the clamp arms 334 from the clamped position to the unclamped position.

In some cases, each clamp arm 334 can be moved between the clamped position and unclamped position using a clamp actuator 350. In some cases, each clamp actuator 350 can be coupled to the arm tube 280 at a location between the clamp arms 334. The use of a clamp actuator 350 can allow for automatic opening and closing of the set of clamp arms 334.

In some cases, the clamp actuators 350 can be prohibited from actuating when the attachment mechanism 352 is not in a raised position. In some cases, winch assembly 316 can be prohibited from lowering the attachment mechanism 352 when a furnace tank is detected as being clamped by the clamp arms 358.

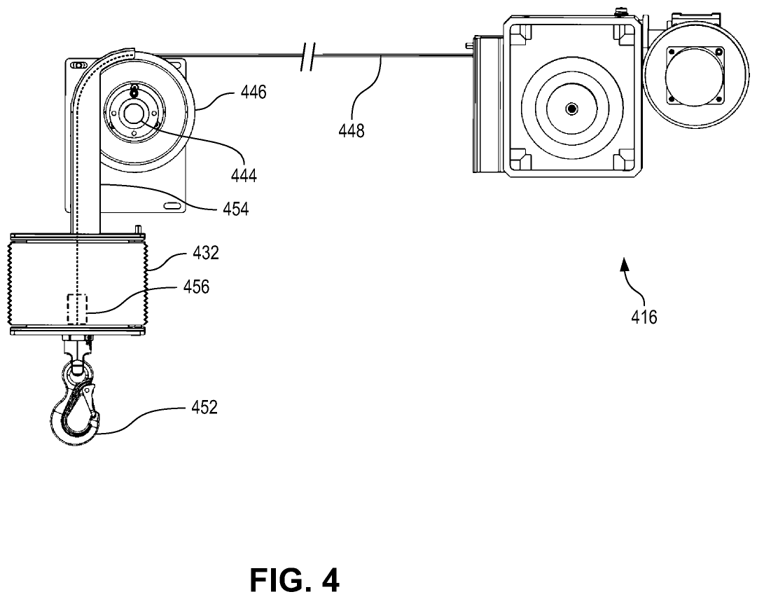

FIG. 4 is a front view of a winch assembly 416 supporting an attachment mechanism 452 in a raised position, according to certain aspects of the present disclosure. Winch assembly 416 can be any suitable winch assembly, such as winch assembly 216 of FIG. 2. For illustrative purposes, the arm tube and certain other components are not depicted. For illustrative purposes, cable collar 456 and certain portions of cable 448 are depicted in dotted lines.

Attachment mechanism 452 can be coupled to the distal end of cable 448, whose proximal end is coupled to the spool of the winch assembly 416. The cable 448 can pass over a pulley 446 that spins on a pulley axis 444 prior to extending downwards and out of the arm tube. In some cases, a pulley cover 454 can be used to ensure the cable 448 remains within the notch of pulley 446. In some cases, other mechanisms (e.g., a pressure roller) can be used to ensure the cable 448 remains within the pulley 446.

The expandable shroud 432 is positioned between the arm tube and the end of the attachment mechanism 452. The top end of the expandable shroud 432 is coupled to the arm tube. The bottom end of the expandable shroud 432 can be coupled to the attachment mechanism 452, coupled to the cable 448, or sandwiched between the attachment mechanism 452 and a cable collar 456. When a cable collar 456 is used, the cable collar 456 can be fixed to the cable 448 and can be weighted to supply downward pressure on the bottom end of the expandable shroud 432 when the cable 448, and thus the attachment mechanism 452, is lowered.

As depicted, the expandable shroud 432 is made with bellows-like folds to permit vertical expansion without compromising the sealed environment within the expandable shroud 432. Other techniques can be used to facilitate expansion of the expandable shroud 432.

When the attachment mechanism 452 is in the raised position, the expandable shroud 432 is in a compressed configuration and the attachment mechanism 452 is adjacent the arm tube. In some cases, a limit switch of the winch assembly 416 can indicate that the attachment mechanism 452 is in the raised position.

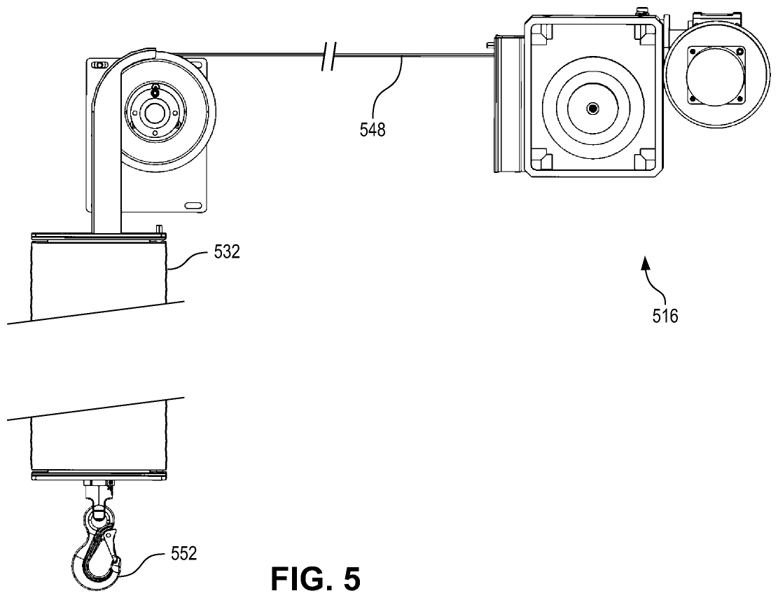

FIG. 5 is a front view of a winch assembly 516 supporting an attachment mechanism in a lowered position, according to certain aspects of the present disclosure. Winch assembly 516 can be any suitable winch assembly, such as winch assembly 216 of FIG. 2.

The attachment mechanism 552 can be moved towards the lowered position by actuating the winch assembly 516 to spool out more cable 548. In the lowered position, the attachment mechanism 552 is spaced apart from the arm tube (e.g., spaced apart greater than when in the raised position). The downward movement of the attachment mechanism 552 pulls on the bottom end of the expandable shroud 532, causing the expandable shroud 532 to expand. As depicted, expandable shroud 532 includes bellows-like folds that have been straightened to accommodate expansion.

In some cases, a limit switch of the winch assembly 516 can indicate that the attachment mechanism 552 is in the lowered position. In some cases, the lowered position can be established based on a length of the cable 548, a lowest useful height for purposes of interacting with the crystal growth apparatus, a floor level, and/or an expansion limit of the expandable shroud 532.

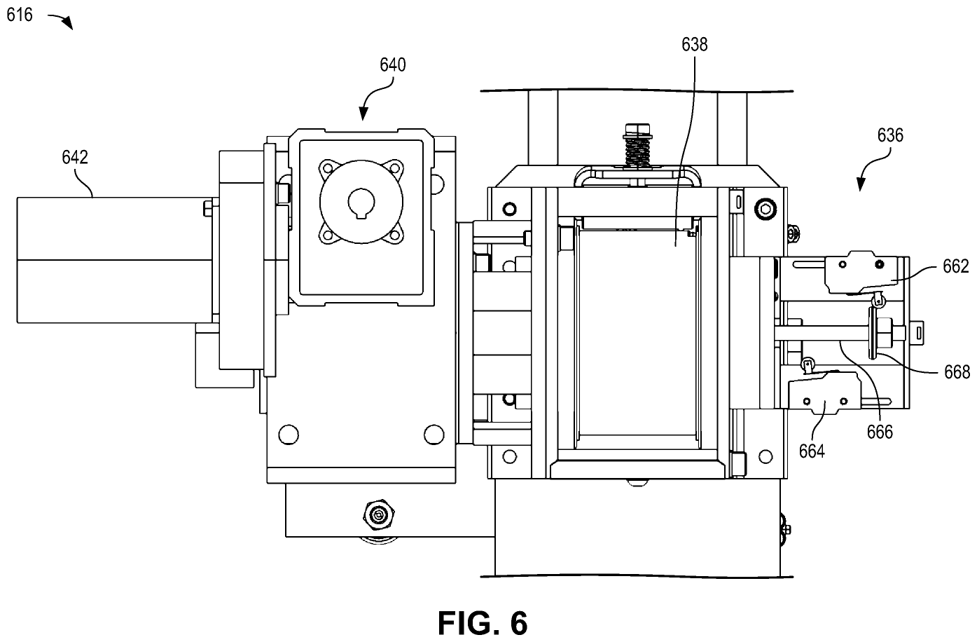

FIG. 6 is a side view of a winch assembly 616 on a lift arm assembly, according to certain aspects of the present disclosure. Winch assembly 616 can be any suitable winch assembly, such as winch assembly 116 of FIG. 1. The winch assembly 616 can include a winch motor 642 that drives a gearbox 640, which in turn drives a spool 638 to rotate. Raising and lowering of the attachment mechanism (e.g., attachment mechanism 452 of FIG. 4) is effected by rotation of the spool 638 in one direction or a reverse direction, respectively.

In some cases, winch assembly 616 includes a limit switch assembly 636. For illustrative purposes, the cover of the limit switch assembly 636 is not depicted. The limit switch assembly 636 can include a leadscrew 666 that is coupled to the spool 638 (e.g., via the spool axel and/or optionally via one or more sprockets or gears). The leadscrew 666 can be caused to rotate proportionally with rotation of the spool 638. A contacting surface 668 (e.g., large washer or the like) can be coupled to the leadscrew 666 (e.g., via a nut) such that rotation of the leadscrew 666 induces axial movement of the contacting surface 668 (e.g., left-and-right movement as depicted in FIG. 6). This axial movement can cause the contacting surface 668 to contact, and thus trigger, one of the limit switches 662, 664.

As depicted, the cable is spooled out such that the attachment mechanism is in a lowered position. In this position, the contacting surface 668 can trigger the lowered position limit switch 662. Actuation of the winch motor 642 to spool up the cable on spool 638 can move the attachment mechanism to the raised position. As the spool 638 rotates to spool up the cable, the contacting surface 668 can move axially towards, and eventually trigger once the raised position is reached, the raised position limit switch 664.

In some cases, alternate limit switch configurations can be used. In some cases, a similar effect can be achieved by using limit switches associated with the attachment mechanism, cable collar, or the like.

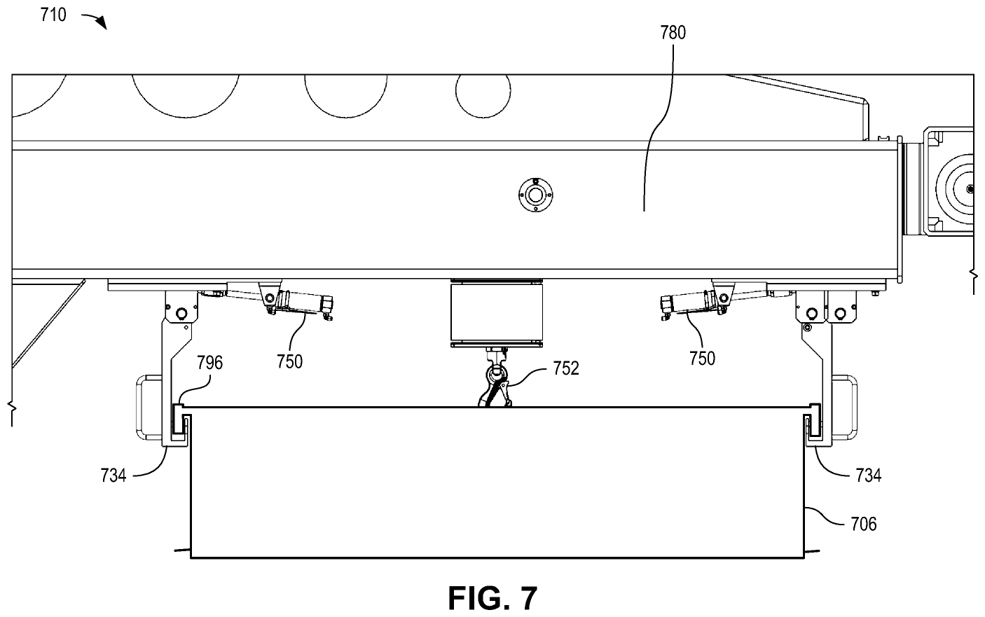

FIG. 7 is a front view of a portion of a lift arm assembly 710 supporting a furnace tank 706, according to certain aspects of the present disclosure. The lift arm assembly 710 can be any suitable lift arm assembly, such as lift arm assembly 110 of FIG. 1. Likewise, furnace tank 706 can be any suitable furnace tank, such as furnace tank 106 of FIG. 1.

The clamp arms 734 of the lift arm assembly 710 are depicted in a clamped position, supporting the lip 796 of the furnace tank 706. In this position, the furnace tank 706 is effectively secured to the arm tube 780 of the lift arm assembly 710. When the furnace tank 706 is secured to the lift arm assembly 710, the attachment mechanism 752 can be in a raised position.

To remove the furnace tank 706 from the lift arm assembly 710, the lift arm assembly 710 can be lowered until the weight of the furnace tank 706 is supported by another surface (e.g., the floor). Continued movement of the lift arm assembly 710 in a downwards direction can move until the corresponding surfaces of the clamp arms 734 pass below the edge of the lip 796. At that time, the clamp actuators 750 can be actuated to rotate the clamp arms 734 into an unclamped position (e.g., rotated away from the furnace tank 706). While the clamp arms 734 are in the unclamped position, the lift arm assembly 710 can be raised until the bottom of the clamp arms 734 at least clear the furnace tank 706. In some cases, the clamp arms 734 can be moved back to a clamped position (e.g., via actuation of clamp actuators 750), although that need not always be the case.

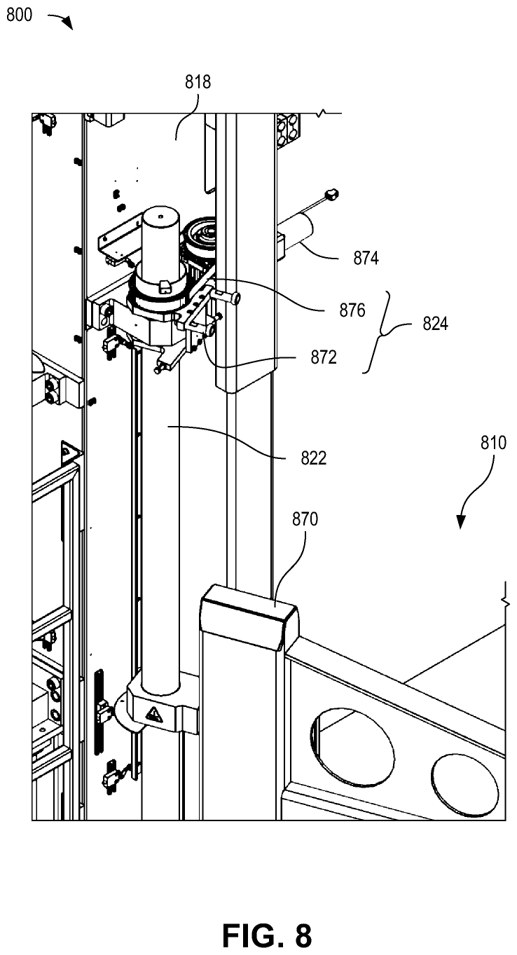

FIG. 8 is an isometric view of a portion of a crystal growing apparatus 800 depicting an arm rotation assembly 824 for rotating a lift arm assembly 810, according to certain aspects of the present disclosure. Crystal growing apparatus 800 can be any suitable crystal growing apparatus, such as crystal growing apparatus 100 of FIG. 1.

The lift arm assembly 810 can be rotationally coupled to vertical shaft 822. The lift arm assembly 810 can be generally free to rotate about vertical shaft 822, or both the lift arm assembly 810 and vertical shaft 822 can rotate with respect to the support tower 818.

The arm rotation assembly 824 can include a keyseat 872 rotationally coupled to the vertical shaft 822. The keyseat 872 can be any suitable structure for receiving a corresponding key region 870 of the lift arm assembly 810. As depicted, the keyseat 872 is a U-shaped piece with two, spaced-apart legs extending from the center of the vertical shaft 822. The keyseat 872 can be driven by an arm rotation driver 874. The arm rotation driver 874 can be a motor that is mechanically coupled to the keyseat 872 via a gearbox and belt 876. As the arm rotation driver 874 is driven, the gearbox provides a mechanical advantage to improve torque, and the belt 876 rotates the keyseat 872 about the axis of the vertical shaft 822 (e.g., axis of rotation 192 of FIG. 1).

When the lift arm assembly 810 is not in a sufficiently high position (e.g., is in a lowered position or below a threshold height), rotation of the keyseat 872 may have no effect on the orientation of the lift arm assembly 810. In fact, in some cases, when the lift arm assembly 810 is not in a sufficiently high position, the arm rotation driver 874 may be prohibited from rotating the keyseat 872. In some cases, however, before the lift arm assembly 810 can be raised above a threshold height, the rotation driver 874 rotates the keyseat 872 to align with the lift arm assembly 810.

The lift arm assembly 810, can include a key region 870. The key region 870 can be shaped to be received by, or otherwise mechanically interact with, the keyseat 872 when the lift arm assembly 810 is raised to a sufficient height (e.g., at or greater than a threshold height). When at or above the threshold height, rotation of the keyseat 872 can impart rotational forces on the key region 870, thus inducing the lift arm assembly 810 to rotate about the axis of the vertical shaft 822 (e.g., axis of rotation 192 of FIG. 1).

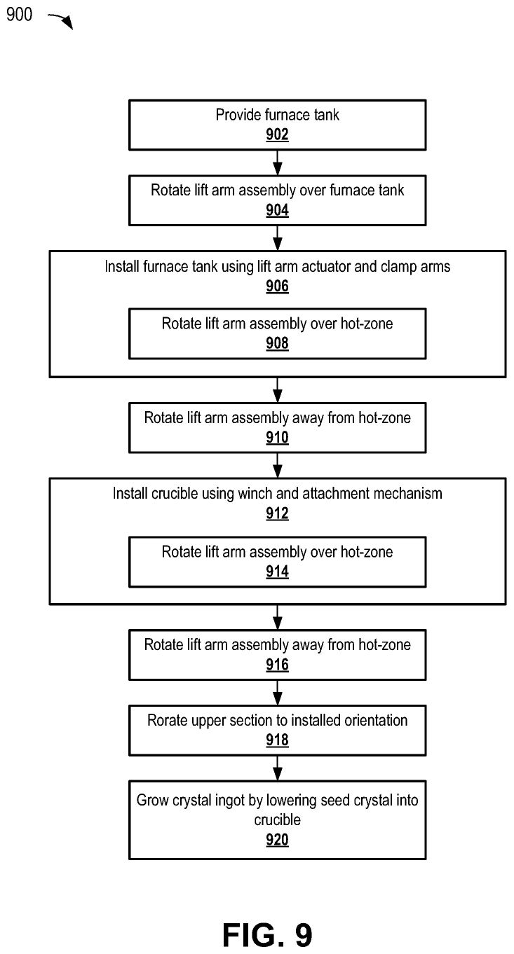

FIG. 9 is a flowchart depicting a process 900 of using a crystal growing apparatus with a lift arm assembly, according to certain aspects of the present disclosure. Process 900 can be used with any suitable crystal growing apparatus, such as crystal growing apparatus 100 of FIG. 1.

At block 902, a furnace tank is provided. The furnace tank can be provided to a side of the crystal growing apparatus, and not yet within the hot-zone of the crystal growing apparatus. At block 904, the lift arm is rotated over the furnace tank. Since the furnace tank is not yet within the hot zone, the lift arm may be in a displaced orientation after block 904.

At block 906, the furnace tank is installed using the lift arm actuator and the clamp arms. Installing the furnace tank at block 906 can include moving the clamp arms to unclamped positions and lowering the lift arm assembly to the furnace tank (e.g., so the clamp arms pass sufficiently below the lip of the furnace tank). Lowering the lift arm assembly is accomplished by actuating the lift arm actuator. Once the lift arm assembly is in a sufficiently low position, the clamp arms can be moved to clamped positions. The lift arm assembly can then be raised using the lift arm actuator. As the lift arm assembly raises, the clamp arms in the clamped positions will engage the lip of the furnace tank, thus lifting the furnace tank.

After the furnace tank is lifted to a sufficient height, the lift arm apparatus is rotated over the hot-zone at block 908. In some cases, rotating the lift arm apparatus over the hot-zone at block 908 includes raising the lift arm assembly to an upper height or above a threshold height, then actuating an arm rotation driver to rotate a keyseat, which engages and rotates a key region of the lift arm assembly to effect rotation of the lift arm assembly. In some cases, the lift arm apparatus is rotated using other means, such as manually.

After the lift arm apparatus is rotated over the hot-zone, block 906 can continue by lowering the lift arm apparatus until the furnace tank is resting on a supporting surface below the furnace tank. Then, the lift arm apparatus can be lowered further until the clamping portions of the clamp arms clear the lip of the furnace tank, allowing the clamp arms to be moved to the unclamped position. Thereafter, the lift arm apparatus can be raised, leaving the furnace tank installed within the hot-zone receiving space of the hot-zone.

At block 910, the lift arm assembly can be rotated away from the hot-zone. In some cases, rotation of the lift arm assembly is effected by an arm rotation apparatus similarly to block 908, although that need not always be the case. Rotating the lift arm assembly away from the hot-zone at block 910 can result in the lift arm assembly being in a displaced orientation.

At block 912, a crucible can be installed using the winch and attachment mechanism. Block 912 can include providing a crucible under the lift arm assembly. The crucible can be pre-charged (e.g., provided with the meltable material (e.g., solid silicon) that will be used to grow the crystal). The meltable material in the pre-charged crucible can be in a solid state, and can be at an ambient temperature, although that need not always be the case. The winch can lower the attachment mechanism down to the crucible's cover. The attachment mechanism can be coupled to the crucible via one or more lift points on the crucible cover. The winch can be actuated to raise the crucible to a sufficient height, which can be the raised position or another height.

After the pre-charged crucible is lifted to a sufficient height, the lift arm apparatus is rotated over the hot-zone at block 914. Rotating the lift arm assembly at block 914 can be performed similarly to block 908.

After the lift arm apparatus is rotated over the hot-zone, block 912 can continue by actuating the winch to lower the attachment mechanism, and thus the crucible, until the crucible is resting on a supporting surface below the crucible (e.g., the crucible support shaft). Then, the crucible cover can be decoupled from the crucible base while remaining attached to the attachment mechanism. Decoupling the crucible cover from the crucible base can include depressurizing the crucible cover/crucible based connection. In some alternate cases, the attachment mechanism can be detached form the crucible cover and the crucible cover can be separately removed. The attachment mechanism, alone or with an attached crucible cover, can be raised by actuation of the winch, and the lift arm apparatus can be rotated to a displaced orientation. If the crucible cover remains attached to the attachment mechanism, the attachment mechanism and crucible cover can be lowered, the crucible cover can be removed from the attachment mechanism, and the attachment mechanism can be raised again.

In some optional cases, the lift arm assembly can be lowered or raised during block 912, although that need not always be the case. In some cases, block 912 can be performed without raising or lowering the lift arm assembly.

At block 916, the lift arm apparatus can be moved away from the hot-zone, similarly to block 910.

At block 918, the upper section (e.g., receiving tube and seed lift assembly) can be rotated to the installed orientation. After rotating to the installed orientation, the upper section can be coupled to the furnace tank. At block 920, a crystal ingot can be grown by lowering the seed crystal into the crucible, to the melt. Growth of the crystal ingot can continue as the seed crystal is raised and rotated in an opposite direction to a direction of rotation of the crucible.

The lift arm actuator has a maximum speed (e.g., vertical mm/s) for raising or lowering the lift arm apparatus. The winch, however, operates at speeds (e.g., vertical mm/s of the attachment mechanism) that are far beyond those of the lift arm actuator. For example, in some cases, the winch can operate at vertical speeds that are tens or hundreds times faster than the vertical speed of the lift arm actuator.

Thus, while the slow movement of the lift arm actuator may be used during blocks 906 and 908, that slow movement can be replaced by the fast moving winch in blocks 912, 914. Additionally, when an arm rotation assembly is used to rotate the lift arm assembly, there is no need to wait for the lift arm assembly to reach its sufficient height after the crucible has been placed in the furnace tank, since the lift arm assembly can remain at a sufficient height and use only the winch to raise and lower the crucible.

While process 900 is described with reference to certain blocks in certain orders, any suitable order can be used, along with additional and/or fewer blocks. For example, in some cases process 900 can proceed without blocks 902, 904, 906, 908, 910, in which case process 900 may be primarily used to install a crucible and grow a crystal ingot. In another example, process 900 can include performing certain blocks in a reverse order and/or in a reverse fashion (e.g., rotating upper section away from the installed orientation instead to the installed orientation) after a crystal has been grown, such as to uninstall the crucible and/or the furnace tank after a crystal has been grown.

The foregoing description of certain aspects of the present disclosure, including illustrated implementations, has been presented only for the purpose of illustration and description and is not intended to be exhaustive or limiting to the precise forms disclosed. Numerous modifications, adaptations, and uses thereof will be apparent to those skilled in the art. Numerous changes to the disclosed implementations can be made in accordance with the disclosure herein, without departing from the spirit or scope of the invention. Thus, the breadth and scope of the present invention should not be limited by any of the above described implementations.

Although the invention has been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

The terminology used herein is for the purpose of describing particular implementations only, and is not intended to be limiting of the invention. As used herein, the singular forms “a,” “an,” and “the” are intended to include the plural forms as well, unless the context clearly indicates otherwise. Furthermore, to the extent that the terms “including,” “includes,” “having,” “has,” “with,” or variants thereof, are used in either the detailed description and/or the claims, such terms are intended to be inclusive in a manner similar to the term “comprising.”

One or more elements or aspects or steps, or any portion(s) thereof, from one or more of any of claims 1 to 20 below can be combined with one or more elements or aspects or steps, or any portion(s) thereof, from one or more of any of the other claims 1 to 20 or combinations thereof, to form one or more additional implementations and/or claims of the present disclosure.

What is claimed is:

1. A lift arm assembly for a crystal growing apparatus, comprising:
a lift arm body having an arm upright and an arm tube extending distally from the arm upright;
a cable having a proximal region and a distal region;
a winch coupled to the lift arm body, the winch having a spool coupled to the proximal region of the cable to move the distal region between a raised position and a lowered position;
a pulley positioned within the arm tube for supporting the cable and directing the cable through a cable opening of the arm tube; and
an expandable shroud having a top end coupled to the arm tube around the cable opening and a bottom end coupled to the distal region of the cable, wherein a sealed environment is defined in part by the expandable shroud, the distal region of the cable, and the arm tube, wherein the expandable shroud is in a compressed configuration when the distal region of the cable is in a raised position, and wherein the expandable shroud is in an expanded configuration when the distal region of the cable is in a lowered position.

2. The lift arm assembly of claim 1, further comprising a set of clamp arms rotatably coupled to and extending below the arm tube, wherein each clamp arm of the set of clamp arms is movable between a clamped position and an unclamped position, and wherein the expandable shroud is positioned between the clamp arms of the set of clamp arms.

3. The lift arm assembly of claim 2, further comprising one or more clamp actuators coupled to the lift arm body and coupled to the clamp arms of the set of clamp arms, wherein actuation of the one or more clamp actuators moves the clamp arms of the set of clamp arms between the clamped position and unclamped position.

4. The lift arm assembly of claim 3, wherein:
the set of clamp arms includes a first clamp arm and a second clamp arm;
the one or more actuators includes a first piston actuator and a second piston actuator coupled respectively to the first clamp arm and the second clamp arm;
the first piston actuator is coupled to the arm tube between the first clamp arm and the second clamp arm and is extendable to move the first clamp arm towards the clamped position; and
the second piston actuator is coupled to the arm tube between the first clamp arm and the second clamp arm and is extendable to move the second clamp arm towards the clamped position.

5. The lift arm assembly of claim 3, further comprising a controller coupled to the one or more clamp actuators, wherein the controller disallows actuation of the one or more clamp actuators when the distal region of the cable is not in a raised position.

6. The lift arm assembly of claim 2, wherein:
the set of clamp arms includes a first clamp arm and a second clamp arm;
the first clamp arm, the second clamp arm, the expandable shroud, and the winch are positioned within a vertical plane intersecting the arm tube and the arm upright; and
the expandable shroud is positioned equidistant from the first clamp arm and the second clamp arm.

7. The lift arm assembly of claim 1, wherein the distal region of the cable includes an attachment mechanism that is removably couplable to a crucible cover, the bottom end of the expandable shroud being coupled to the attachment mechanism.

8. The lift arm assembly of claim 1, wherein the winch is coupled to a distal end of the arm tube.

9. The lift arm assembly of claim 1, wherein the winch further includes limit switch assembly mechanically coupled to the spool to output a first signal when the distal region of the cable is in the raised position and a second signal when the distal region of the cable is in a lowered position.

10. The lift arm assembly of claim 1, wherein the arm upright includes one or more bearings for rotatably supporting the lift arm body on a vertical shaft, and wherein a top end of the arm upright includes a key region, wherein the key region is removably insertable within a keyseat to encourage rotation of the lift arm body about the vertical shaft.

11. A crystal growing apparatus, comprising:
a furnace tank having an opening;
a support tower;
an upper section removably couplable to the opening to establish a crystal growing chamber, the upper section comprising a receiving tube coupled to a seed lift assembly, wherein the upper section is rotatably coupled to the support tower to rotate between an installed orientation and an uninstalled orientation, wherein the upper section is positioned over the furnace tank when in the installed orientation, and wherein the upper section is rotated away from the furnace tank when in the uninstalled orientation;
a lift arm assembly rotatably coupled to the support tower to rotate between a hot-zone orientation and a displaced orientation, the lift arm assembly including:
a lift arm body comprising an arm upright and an arm tube extending distally from the arm upright;
a cable having a proximal region and a distal region, the distal region including an attachment mechanism that is removably couplable to a crucible cover of a crucible positionable within the furnace tank;
a winch coupled to the lift arm body, the winch having a spool coupled to the proximal region of the cable to move the distal region between a raised position and a lowered position at a first speed;
a pulley positioned within the arm tube for supporting the cable and directing the cable through a cable opening of the arm tube; and
an expandable shroud having a top end coupled to the arm tube around the cable opening and a bottom end coupled to the distal region of the cable, wherein a sealed environment is defined in part by the expandable shroud, the distal region of the cable, and the arm tube, wherein the expandable shroud is in a compressed configuration when the distal region of the cable is in a raised position, and wherein the expandable shroud is in an expanded configuration when the distal region of the cable is in a lowered position; and
a lift arm actuator actuatable to move the lift arm assembly between an upper position and a lower position up to a second speed, wherein the first speed is faster than the second speed.

12. The crystal growth apparatus of claim 11, wherein the lift arm assembly further includes a set of clamp arms rotatably coupled to and extending below the arm tube, wherein:
each clamp arm of the set of clamp arms is movable between a clamped position and an unclamped position;
the set of clamp arms are positioned such that when the lift arm assembly is in the hot-zone orientation and the lift arm actuator is actuated to move the set of clamp arms passed a lip of the furnace tank, the set of clamp arms do not engage the lip when in the unclamped position and engage the lip when in the clamped position; and
the expandable shroud is positioned between the clamp arms of the set of clamp arms

13. The crystal growing apparatus of claim 12, wherein the lift arm assembly further includes one or more clamp actuators coupled to the lift arm body and coupled to the clamp arms of the set of clamp arms, wherein actuation of the one or more clamp actuators moves the clamp arms of the set of clamp arms between the clamped position and unclamped position.

14. The crystal growing apparatus of claim 13, wherein:
the set of clamp arms includes a first clamp arm and a second clamp arm;
the one or more actuators includes a first piston actuator and a second piston actuator coupled respectively to the first clamp arm and the second clamp arm;
the first piston actuator is coupled to the arm tube between the first clamp arm and the second clamp arm and is extendable to move the first clamp arm towards the clamped position; and
the second piston actuator is coupled to the arm tube between the first clamp arm and the second clamp arm and is extendable to move the second clamp arm towards the clamped position.

15. The crystal growing apparatus of claim 13, further comprising a controller coupled to the one or more clamp actuators, wherein the controller disallows actuation of the one or more clamp actuators when the distal region of the cable is not in a raised position.

16. The crystal growing apparatus of claim 12, wherein:
the set of clamp arms includes a first clamp arm and a second clamp arm;
the first clamp arm, the second clamp arm, the expandable shroud, and the winch are positioned within a vertical plane intersecting the arm tube and the arm upright; and
the expandable shroud is positioned equidistant from the first clamp arm and the second clamp arm.

17. The crystal growing apparatus of claim 11, wherein the winch is coupled to a distal end of the arm tube.

18. The crystal growing apparatus of claim 1, further comprising:
a vertical shaft coupled to the support tower for supporting the lift arm assembly, wherein the arm upright includes one or more bearings for rotatably supporting the lift arm body on the vertical shaft;
an arm rotation assembly rotatably coupled to the vertical shaft above the lift arm assembly, the arm rotation assembly including a keyseat, wherein a top end of the arm upright of the lift arm assembly includes a key region that is sized for removable insertion into the keyseat when the lift arm assembly is raised to the upper position, wherein the key region is spaced apart from the keyseat when the lift arm assembly is in the lower position; and
an arm rotation driver mechanically coupled to the arm rotation assembly to rotate the keyseat about the vertical shaft.

19. A method for using a crystal growing apparatus, the method comprising:
providing a furnace tank having a lip;
positioning a lift arm assembly over the furnace tank, wherein the lift arm assembly is rotatably coupled to a support tower, the lift arm assembly including:
a lift arm body comprising an arm upright and an arm tube extending distally from the arm upright;
a cable having a proximal region and a distal region, the distal region including an attachment mechanism that is removably couplable to the crucible cover;
a winch coupled to a distal end of the lift arm body, the winch having a spool coupled to the proximal region of the cable to move the attachment mechanism between a raised position and a lowered position at a first speed;
a pulley positioned within the arm tube for supporting the cable and directing the cable through a cable opening of the arm tube;
an expandable shroud having a top end coupled to the arm tube around the cable opening and a bottom end coupled to the distal region of the cable, wherein a sealed environment is defined in part by the expandable shroud, the distal region of the cable, and the arm tube, wherein the expandable shroud is in a compressed configuration when the attachment mechanism is in a raised position, and wherein the expandable shroud is in an expanded configuration when the attachment mechanism is in a lowered position; and
a set of clamp arms rotatably coupled to and extending below the arm tube, wherein each clamp arm of the set of clamp arms is movable between a clamped position and an unclamped position;
installing the furnace tank, wherein installing the furnace tank includes:
moving each clamp arm of the set of clamp arms to the unclamped position;
actuating a lift arm actuator to lower the lift arm assembly up to a first speed until each clamp arm of the set of clamp arms passes below the lip of the furnace tank;
moving each clamp arm of the set of clamp arms to the clamped position;
actuating the lift arm actuator to raise the lift arm assembly and move each clamp arm of the set of clamp arms to engage the lip of the furnace tank;
rotating the lift arm assembly to a hot-zone orientation;
actuating the lift arm actuator to lower the lift arm assembly until the furnace tank rests within a furnace tank receiving space;
moving each clamp arm of the set of clamp arms to the unclamped position; and
actuating the lift arm actuator to raise the lift arm assembly;
providing a crucible filled with a meltable material, the crucible having a crucible cover removably coupled to a crucible base;
rotating the lift arm assembly to a position over the crucible;
installing the crucible, wherein installing the crucible includes:
actuating the winch to lower the attachment mechanism at a second speed, wherein the second speed is greater than the first speed;
coupling the attachment mechanism to the crucible cover;
actuating the winch to raise the attachment mechanism and crucible;
rotating the lift arm assembly to the hot-zone orientation;
actuating the winch to lower the attachment mechanism and crucible until the crucible rests within the furnace tank;
disconnecting the attachment mechanism from the crucible base; and
actuating the winch to raise the attachment mechanism;
rotating the lift arm assembly away from the hot-zone orientation;
rotating an upper section to an installed orientation over the furnace tank, the upper section being rotatably coupled to the support tower, the upper section having a seed lift assembly coupled to a receiving tube, the seed lift assembly supporting a seed crystal on a cable; and
growing a crystal ingot by lowering the seed crystal to the meltable material in the crucible and raising the seed crystal while counter-rotating the seed crystal and the crucible base.

20. The method of claim 19, wherein rotating the lift arm assembly to the hot-zone orientation comprises:
engaging a key region of the lift arm assembly with a keyseat of an arm rotation assembly, wherein the key region is positioned at a top end of the arm upright of the lift arm assembly, wherein the lift arm assembly and the arm rotation assembly are rotatably coupled to a vertical shaft that is coupled to the support tower, wherein the key region engages the keyseat when the lift arm assembly is in an upper position, and wherein the key region is spaced apart from the keyseat when the lift arm assembly is in a lower position; and
rotating the keyseat of the arm rotation assembly, wherein rotation of the keyseat when the key region is engaged with the keyseat induces rotation of the lift arm assembly.
